(19) United States
(12) Patent Application Publication
(10) Pub. No.: US 2025/0015005 A1
(43) Pub. Date: Jan. 9, 2025

(54) SEMICONDUCTOR PACKAGE

(71) Applicant: Samsung Electronics Co., Ltd., Suwon-si (KR)

(72) Inventor: Keunyoung Lee, Suwon-si (KR)

(21) Appl. No.: 18/421,110

(22) Filed: Jan. 24, 2024

(30) Foreign Application Priority Data
Jul. 7, 2023 (KR) 10-2023-0088461

(51) Int. Cl. H01L 23/538; H01L 23/00; H01L 25/065; H01L 25/10; H10B 80/00

(52) U.S. Cl. CPC H01L 23/5382; H01L 23/5386; H01L 25/0652; H01L 25/105; H10B 80/00; H01L 24/16; H01L 24/32; H01L 24/48; H01L 24/73; H01L 2224/16227; H01L 2224/16238; H01L 2224/32058; H01L 2224/32059; H01L 2224/32145; H01L 2224/32225; H01L 2224/48147; H01L 2224/48227; H01L 2224/73204; H01L 2224/73215; H01L 2224/73265; H01L 2225/1023; H01L 2225/1041; H01L 2225/1058; H01L 2924/1431; H01L 2924/1434

(57) ABSTRACT

A semiconductor package includes: a plurality of transmission external terminals; a plurality of reception external terminals; a semiconductor chip including a plurality of transmission pads, a plurality of reception pads, and at least one option pad; a plurality of transmission lanes electrically connected between the plurality of transmission external terminals and the plurality of transmission pads; and a plurality of reception lanes electrically connected between the plurality of reception external terminals and the plurality of reception pads. The semiconductor chip is configured to swap signals or connections for the plurality of transmission pads, or swap signals or connections for the plurality of reception pads, selectively depending on an input of the at least one option pad.

### CROSS-REFERENCE TO RELATED APPLICATION(S)

This application claims benefit of priority to Korean Patent Application No. 10-2023-0088461 filed on Jul. 7, 2023, in the Korean Intellectual Property Office, the disclosure of which is incorporated herein by reference in its entirety.

### BACKGROUND

The present disclosure relates to a semiconductor package.

Recently, high performance and high capacity are typically required in semiconductor packages mounted on electronic devices. Accordingly, a semiconductor package in which a plurality of semiconductor chips are embedded together has been developed, and a data transmission rate of signals transmitted and received between the plurality of semiconductor chips is gradually increasing.

Data transmission and reception between a plurality of semiconductor chips may be implemented through lanes between the plurality of semiconductor chips, and with an increase in a data transmission rate of signals passing through the lanes, the performance of the lanes (e.g., impedance matching accuracy, energy efficiency, and noise shielding performance) may be an important factor to consider.

Accordingly, the high performance and high capacity of semiconductor packages may require higher design optimality of the lanes, and higher design optimality of each of the plurality of semiconductor chips.

### SUMMARY

An aspect of the present disclosure includes a semiconductor package that can flexibly improve the design optimality of lanes and/or a semiconductor chip of a semiconductor package.

According to an aspect of the present disclosure, a semiconductor package includes: a plurality of transmission external terminals; a plurality of reception external terminals; a semiconductor chip including a plurality of transmission pads, a plurality of reception pads, and at least one option pad; a plurality of transmission lanes electrically connected between the plurality of transmission external terminals and the plurality of transmission pads; and a plurality of reception lanes electrically connected between the plurality of reception external terminals and the plurality of reception pads. The semiconductor chip is configured to swap signals or connections for the plurality of transmission pads, or swap signals or connections for the plurality of reception pads, selectively depending on an input of the at least one option pad.

According to an aspect of the present disclosure, a semiconductor package includes: a plurality of external terminals; a semiconductor chip including a plurality of lane pads formed in a plurality of lanes, and a plurality of option pads; and a plurality of lanes electrically connected between the plurality of external terminals and the plurality of lane pads, wherein each set of the plurality of lane pads includes a plurality of line pads, the semiconductor chip is configured to swap signals or connections for the plurality of lane pads, selectively depending on an input of a first set of the plurality of option pads, and the semiconductor chip is configured to swap signals or connections for the plurality of line pads, selectively depending on an input of a second set of the plurality of option pads.

According to an aspect of the present disclosure, a semiconductor package includes: a plurality of transmission external terminals; a plurality of reception external terminals; a semiconductor chip including a plurality of transmission pads and a plurality of reception pads; a plurality of transmission lanes electrically connected between the plurality of transmission external terminals and the plurality of transmission pads; and a plurality of reception lanes electrically connected between the plurality of reception external terminals and the plurality of reception pads, wherein the semiconductor chip includes an interface circuit configured to generate transmission signals or convert reception signals according to a specific interface manner, and the semiconductor chip is configured so that at least one of an electrical connection relationship between a plurality of transmission terminals of the interface circuit and the plurality of transmission pads and an electrical connection relationship between a plurality of reception terminals of the interface circuit and the plurality of reception pads is switched from a variable state to a fixed state.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a view illustrating a semiconductor package according to an example embodiment of the present disclosure;

FIGS. 1B to 1D are views illustrating a swap operation according to an input of an option pad of a semiconductor package according to an example embodiment of the present disclosure;

FIG. 2A is a plan view illustrating a semiconductor package according to an example embodiment of the present disclosure;

FIGS. 2B to 2D are plan views illustrating a swap operation according to an input of an option pad of a semiconductor package according to an example embodiment of the present disclosure;

FIGS. 3A to 3C are plan views illustrating a difference in a swap operation according to an input of some of a plurality of option pads of a semiconductor package according to an example embodiment of the present disclosure and an input of others thereof;

FIG. 4A is a perspective view illustrating a semiconductor package according to an example embodiment of the present disclosure;

FIGS. 4B and 5 are side views illustrating a semiconductor package according to an example embodiment of the present disclosure; and

FIGS. 6A and 6B are views illustrating a semiconductor package according to an example embodiment of the present disclosure.

### DETAILED DESCRIPTION

In the following detailed description of the present disclosure, references are made to the accompanying drawings that show, by way of illustration, specific example embodiments in which the present disclosure may be practiced. These example embodiments are described in sufficient detail to enable those skilled in the art to implement the present disclosure. It should be understood that various embodiments of the present disclosure, although different, are not necessarily mutually exclusive. For example, specific features, structures, and characteristics described herein, in connection with an example embodiment, may be implemented within other embodiments without departing from the spirit and scope of the present disclosure. In addition, it should be understood that the location or arrangement of individual elements within each disclosed embodiment may be modified without departing from the spirit and scope of the present disclosure. The following detailed description is, therefore, not to be taken in a limiting sense, and the scope of the present disclosure is defined only by the appended claims, appropriately interpreted, along with the full range of equivalents to what the claims claim. The similar reference numerals refer to the same or similar functions in various aspects.

Hereinafter, example embodiments will be described in detail with reference to the accompanying drawings so that those skilled in the art may easily implement the present disclosure.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes. Components described as being communicatively connected are electrically connected in a state in which a signal or voltage can be passed between the components.

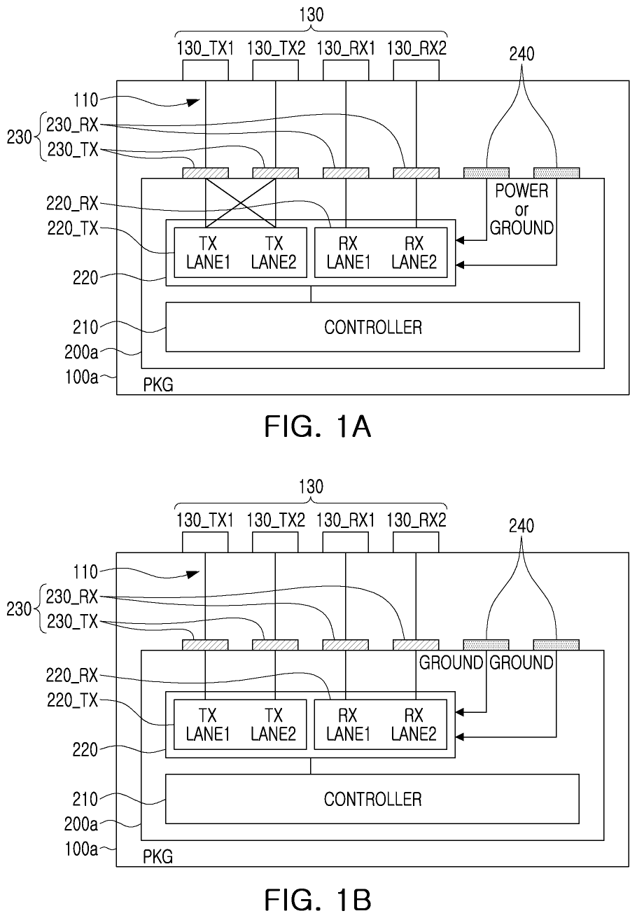

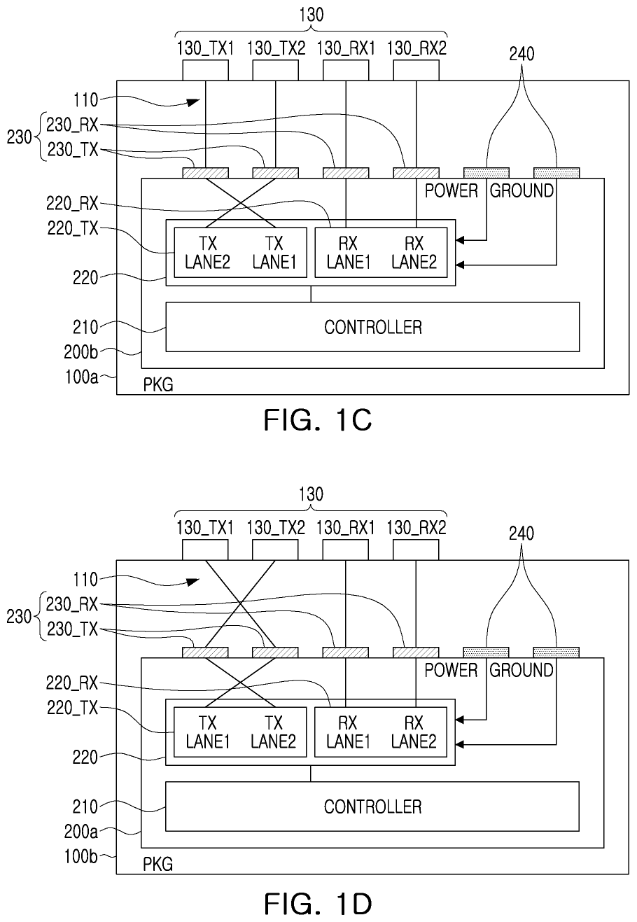

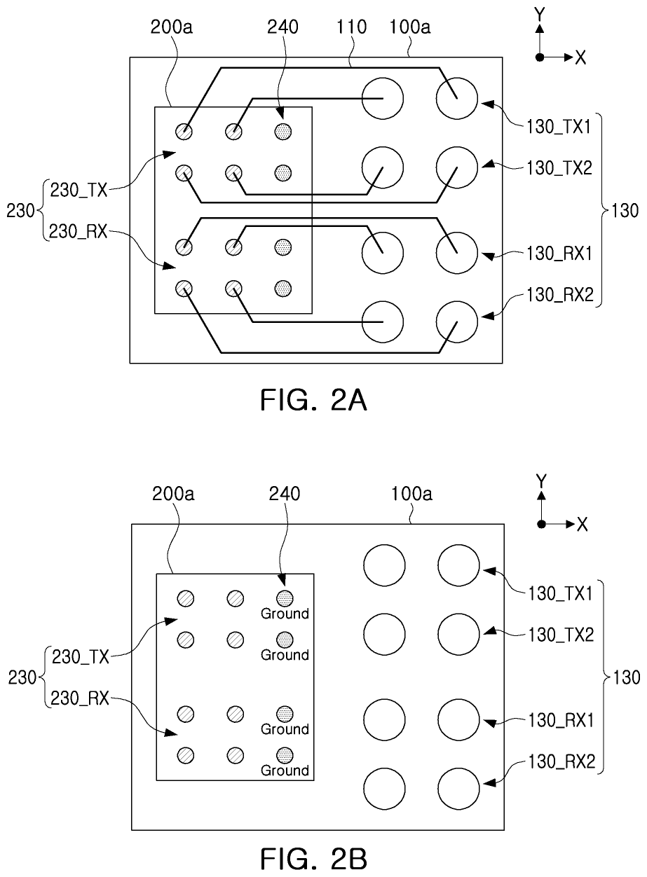

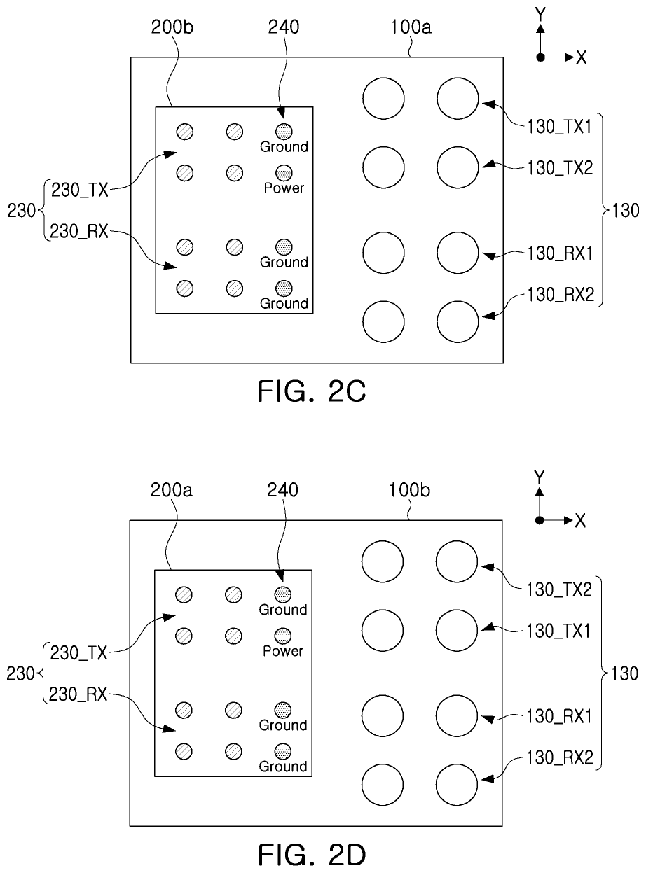

Referring to FIGS. 1A and 2A, a semiconductor package according to an example embodiment of the present disclosure may include a plurality of external terminals 130, a semiconductor chip 200a, and a plurality of lanes 110. The semiconductor chip 200a may include a plurality of pads 230 and at least one option pad 240, and a substrate 100a may provide an arrangement space for the plurality of external terminals 130, the semiconductor chips 200a, and the plurality of lanes 110.

The substrate 100a may have a structure on which at least one wiring layer and at least one insulating layer are alternately laminated, and may be a printed circuit board, but the present disclosure is not limited thereto. For example, at least one wiring layer may include a wiring layer or a redistribution line, and the plurality of lanes 110 may be implemented with at least one of the wiring layer, the redistribution line, and conductive vias. The plurality of lanes 110 may be included in the at least one wiring layer.

The plurality of external terminals 130, also described as external connection terminals or package terminals, may provide electrical connection paths to an additional semiconductor chip or an additional substrate. For example, the plurality of external terminals 130 may be at least one of a bump, a solder ball, a bonding wire, and a post, and may electrically connect and fix an additional semiconductor chip (and/or additional substrate) provided from the outside to the substrate 100a.

The semiconductor chip 200a may be electrically connected to the plurality of external terminals 130 through the plurality of pads 230 and the plurality of lanes 110. The semiconductor package may include a plurality of transmission external terminals 130_TX1 and 130_TX2 and a plurality of reception external terminals 130_RX1 and 130_RX2. The semiconductor chip 200a may transmit transmission signals to the plurality of transmission external terminals 130_TX1 and 130_TX2 and receive reception signals from the plurality of reception external terminals 130_RX1 and 130_RX2.

The semiconductor chip 200a may include a controller 210 and an interface circuit 220. For example, the controller 210 may receive signals from outside (e.g., a processor of an electronic device, and a computing system), generate control information based on the signals, and the interface circuit 220 may generate a plurality of transmission signals including the control information or generate reception information from a plurality of reception signals. For example, the controller 210 may control a plurality of memory chips by generating the control information and using the reception information according to the universal flash storage (UFS) method.

For example, the interface circuit 220 may correspond to a physical layer and/or a protocol layer of a network communication layer, and the controller 210 may correspond to at least a portion of a protocol layer of the network communication layer and/or an application. For example, when the semiconductor chip 200a generates transmission signals and converts reception signals according to the M-PHY of the mobile industry processor interface (MIPI), the M-PHY may correspond to a physical layer, and a protocol layer may correspond to a CSI-3 of the MIPI.

The semiconductor chip 200a may include the interface circuit 220 configured to generate transmission signals or convert reception signals according to a specific interface method (e.g., the M-PHY of the mobile industry processor interface (MIPI)), and the interface circuit 220 may include a transmission interface circuit 220_TX configured to generate transmission signals, and a reception interface circuit 220_RX configured to convert reception signals. The transmission interface circuit 220_TX may transmit first transmission signals through first transmission terminals TX LANE1 and may transmit second transmission signals through second transmission terminals TX LANE2. The reception interface circuit 220_RX may receive first reception signals through first reception terminals RX LANE1 and may receive second reception signals through second reception terminals RX LANE2. It should be noted that a physical representation of these first transmission terminals TX LANE1, second transmission terminals TX LANE2, first reception terminals RX LANE1, and second reception terminals RX LANE2 is not depicted in the drawings, but may be implemented by pads or other conductive nodes within the semiconductor chip 200a. Pads, as described herein, refers to a terminal for connecting between internal circuitry and external circuitry, for example, internal circuitry of a semiconductor chip and an external device. Pads may have a flat external surface and be formed of a conductive material such as a metal.

A data transmission rate of each of transmission signals passing through a plurality of transmission lanes of the plurality of lanes 110 and reception signals passing through a plurality of reception lanes of the plurality of lanes 110 may exceed 3 Gbps. For example, the data transmission rate of signals according to a D-PHY and a C-PHY of the MIPI is less than 3 Gbps, but a data transmission rate of transmission signals and reception signals according to a M-PHY of the MIPI may exceed 3 Gbps, and may be faster depending on a control manner (e.g., UFS) of the controller 210. For example, the data transmission rate according to a UFS 5.0 control manner may be as fast as 24 Gbps or even faster.

With an increase in the data transmission rate of the transmission signals and the reception signals, a fundamental frequency of the transmission signals and the reception signals may increase. With an increase in the fundamental frequency of the transmission signals and the reception signals, the impedance matching freedom of the plurality of lanes 110 may decrease, and the design optimality of the plurality of lanes 110 may be required to be higher.

For example, with an increase in the design optimality of the plurality of lanes 110, a length of unnecessary rotation of some of the plurality of lanes 110 may decrease, and accordingly, an overall length of the plurality of lanes 110 may be shorter as the design optimality of the plurality of lanes 110 increases. With a decrease in the overall length of the plurality of lanes 110, an energy loss in the plurality of lanes 110 of the transmission signals and the reception signals may decrease. With an increase in the data transmission rate (or the fundamental frequency) of the transmission signals and the reception signals, the energy loss may increase, and the design optimality of the plurality of lanes 110 for reducing the energy loss may become more important.

The plurality of pads 230 included in the semiconductor chip 200a may include a plurality of transmission pads 230_TX and a plurality of reception pads 230_RX. The plurality of lanes 110 may include a plurality of transmission lanes and a plurality of reception lanes, the plurality of transmission lanes may be electrically connected between the plurality of transmission pads 230_TX and the plurality of transmission external terminals 130_TX1 and 130TX2, and the plurality of reception lanes may be electrically connected between the plurality of reception pads 230_RX and the plurality of reception external terminals 130_RX1 and 130_RX2.

The design optimality of the plurality of lanes 110 may be advantageously enhanced by fixing at least one of a correspondence relationship between the plurality of transmission pads 230_TX and the plurality of transmission external terminals 130_TX1 and 130TX2, and a correspondence relationship between the plurality of reception pads 230_RX and the plurality of reception external terminals 130_RX1 and 130_RX2.

Meanwhile, with an increase in the data transmission rate of the transmission signals and the reception signals, the data processing speed of the semiconductor chip 200a may be required to increase. As the data processing speed is required to increase, the overall integration and/or complexity of the semiconductor circuits of the semiconductor chip 200a may increase, and the design optimality of the semiconductor chip 200a may also be required to be higher.

When at least one of a correspondence relationship between the plurality of transmission pads 230_TX and the plurality of transmission signals and a correspondence relationship between the plurality of reception pads 230_RX and the plurality of reception signals is variable, the design optimality of the semiconductor chip 200a may be advantageously enhanced.

For example, since first sets and second sets of the transmission signals may be differential from each other, when signals of the first set of the transmission signals have a high value (e.g., a value close to power), the signals of the second set of the transmission signals may have a low value (e.g., a value close to zero). In some semiconductor circuits of the semiconductor chip 200a, the characteristics of processing the high value and the characteristics of processing the low values of transmission signals may be different from each other. That is, a positive/negative relationship of the transmission signals may be a design optimization element of the semiconductor chip 200a. Alternatively, in some of the semiconductor circuits of the semiconductor chip 200a, a processing order of the transmission signals may also be an optimization element. Accordingly, the design optimization of the semiconductor chip 200a may make the processing order of the transmission signals uncertain, and a lane order corresponding to the processing order can also be uncertain. With an increase in the overall integration and/or complexity of the semiconductor circuits of the semiconductor chip 200a, the design optimization element may have a greater impact.

The semiconductor chip 200a may be configured to swap between (e.g., swap signals or connections for) the plurality of transmission pads 230_TX or swap between (e.g., swap signals or connections for) the plurality of reception pads 230_RX, selectively depending on an input of at least one option pad 240. Here, the term ‘swap’ refers to exchange in terms of signals or connections, and may refer to exchange of positive/negative relationships of signals, exchange of the turn of signals, or exchange of the order of signals, but the present disclosure is not limited to thereto. For example, the swap may denote a swap of a correspondence relationship between first and second transmission terminals TX LANE1 and TX LANE2 of the interface circuit 220 and the plurality of transmission pads 230_TX, or a swap of a correspondence relationship between first and second reception terminals RX LANE1 and RX LANE2 and the plurality of reception pads 230_RX.

An electrical connection of the interface circuit 220 of the semiconductor chip 200a to the plurality of lanes 110 and the input of at least one option pad 240 may be implemented after the semiconductor chip 200a is designed and implemented. Accordingly, a particular input of at least one option pad 240 may change at least one of a correspondence relationship between the plurality of transmission pads 230_TX and the plurality of transmission signals and a correspondence relationship between the plurality of reception pads 230_RX and the plurality of reception signals from a variable state to a fixed state, and a particular input of at least one option pad 240 may resolve the uncertainty of at least one of the correspondence relationship between the plurality of transmission pads 230_TX and the plurality of transmission signals, and the correspondence relationship between the plurality of reception pads 230_RX and the plurality of reception signals. For example, the semiconductor chip 200a may change at least one of an electrical connection relationship between the plurality of transmission terminals TX LANE1 and TX LANE2 of the interface circuit 220 and the plurality of transmission pads 230_TX, and an electrical connection relationship between the plurality of reception terminals RX LANE1 and RX LANE2 of the interface circuit 220 and the plurality of reception pads 230_RX from a variable state to a fixed state.

For example, the input of at least one option pad 240 may correspond to and be selected from a ground or power source. For example, a switch connected to ground and power may be controlled by the controller 210 to output either ground or power to the at least one option pad 240.

Alternatively, in some embodiments, the at least one option pad 240 may be connected to a respective at least one external terminal of the package, which receives power or ground voltages when connected to another device. The semiconductor chip 200a may be configured to swap signals or connections for the plurality of transmission pads 230_TX or swap signals or connections for the plurality of reception pads 230_RX (e.g., as one example, swap which transmission pads 230_TX are connected to which transmission terminals TX LANE1 and TX LANE2 or swap which reception pads 230_RX are connected to which reception terminals RX LANE1 and RX LANE2) depending on whether the input of at least one option pad 240 is the power or ground.

FIGS. 1B and 2B illustrate a semiconductor package in a case in which arrangements of first and second transmission terminals TX LANE1 and TX LANE2 and first and second reception terminals RX LANE1 and RX LANE2 of an interface circuit 220 of a semiconductor chip 200a and pads to be connected are in a default setting.

Referring to FIGS. 1B and 2B, when an input of at least one option pad 240 corresponds to a first state such as ground (e.g., in one embodiment, when all option pads 240 are set to receive and output a ground voltage level), first transmission signals may be transmitted to first transmission external terminals 130_TX1 through first transmission terminals TX LANE1 and first transmission lane pads (e.g., a set of pads depicted at the left side of 230_TX), and second transmission signals may be transmitted to second transmission external terminals 130_TX2 through second transmission terminals TX LANE2 and second transmission lane pads (e.g., a set of pads depicted at the right side of 230_TX). First reception signals may be received from first reception external terminals 130_RX1 through first reception pads (the left side of 230_RX) and first reception terminals RX LANE1, and second reception signals may be received from second reception external terminals 130_RX2 through second reception pads (the right side of 230_RX) and second reception terminals RX LANE2.

FIGS. 1C and 2C illustrates a semiconductor package in a case in which arrangements of first and second transmission terminals TX LANE1 and TX LANE2 of an interface circuit 220 of a semiconductor chip 200b and pads to be connected are changed compared to FIGS. 1B and 2B.

Referring to FIGS. 1C and 2C, an arrangement of which terminals of the first and second transmission terminals TX LANE1 and TX LANE2 connect to which pads of the transmission pads 230_TX may be changed during the design optimization process of the semiconductor chip 200b. For example, when one input of a plurality of option pads 240 corresponds to the power, connection target pads of the first and second transmission terminals TX LANE1 and TX LANE2 may be swapped with each other so that the respective transmission pads 230_TX that they connect to and communicate with are swapped. For example, during a swap, the connections to internal electrical pathways change, so that circuitry previously used for communicating second transmission signals with second transmission external terminals 130_TX2 by being communicatively connected to the second transmission external terminals 130_TX2 is instead used to communicate first transmission signals with first external terminals 130_TX1, and circuitry previously used for communicating first transmission signals with first transmission external terminals 130_TX1 by being communicatively connected to the first transmission external terminals 130_TX1 is instead used to communicate second transmission signals with second external terminals 130_TX2. Therefore, in some embodiments, a semiconductor chip 200b comprises an interface circuit 220 configured to generate transmission signals or convert reception signals according to a specific interface manner, and the semiconductor chip 200b is configured to swap a correspondence relationship between the transmission signals and the plurality of transmission pads 230_TX, or swap a correspondence relationship between the reception signals and the plurality of reception pads 230_RX, selectively depending on the input of the at least one option pad 240. In some embodiments, the interface circuit 220 can internally perform the swapping operations (e.g., via a set of switches and/or other circuitry) to change which signals output to which transmission pads 230_TX and to change how reception signals received by the reception pads 230_RX are routed and/or converted. Accordingly, an electrical connection relationship between a plurality of lanes 110 and a plurality of pads 230 may not be affected by the arrangement of the first and second transmission terminals TX LANE1 and TX LANE2. Accordingly, the semiconductor package according to an example embodiment of the present disclosure may flexibly improve the design optimality of the semiconductor chip 200b and the design optimality of the plurality of lanes 110.

Selectively depending on an input of at least one option pad 240, an electrical connection relationship between the plurality of transmission external terminals 130_TX1 and 130_TX2 and a plurality of transmission pads 230_TX may be determined so that an overall length of a plurality of transmission lanes of the plurality of lanes 110 for particular types of signals is the shortest (e.g., is shorter than an overall length of other lanes of the transmission lanes), or an electrical connection relationship between the plurality of reception external terminals 130_RX1 and 130_RX2 and a plurality of reception pads 230_RX may be determined so that an overall length of a plurality of reception lanes of the plurality of lanes 110 for particular types of signals is the shortest (e.g., is shorter than an overall length of other lanes of the reception lanes). This may be implemented by swapping signals or connections for the plurality of transmission pads 230_TX or swapping signals or connections for the plurality of reception pads 230_RX. With a decrease in the overall length of the plurality of lanes 110 (e.g., a decrease in combined length of the plurality of lanes 110 and/or decrease in the length of each particular lane 110), a transmission energy loss of the transmission signals and the reception signals may be reduced, and the impedance matching efficiency and noise shielding efficiency may be further increased.

FIGS. 1D and 2D illustrate a different embodiment of a semiconductor package in a case in which arrangements of first and second transmission terminals TX LANE1 and TX LANE2 and first and second reception terminals RX LANE1 and RX LANE2 of an interface circuit 220 of a semiconductor chip 200a are default.

Referring to FIGS. 1D and 2D, when an input of one of a plurality of option pads 240 corresponds to power (e.g., a power voltage level), connection target pads of the first and second transmission terminals TX LANE1 and TX LANE2 may be swapped with each other. Accordingly, first transmission signals may be transmitted to first transmission external terminals 130_TX1 through the first transmission terminals TX LANE1 and second transmission lane pads (the right side of 230_TX), and second transmission signals may be transmitted to second transmission external terminals 130_TX2 through the second transmission terminals TX LANE2 and first transmission lane pads (the left side of 230_TX). First reception signals may be received from first reception external terminals 130_RX1 through second reception pads (the right side of 230_RX) and first reception terminals RX LANE1, and second reception signals may be received from second reception external terminals 130_RX2 through first reception pads (the left side of 230_RX) and second reception terminals RXE2.

In other words, selectively depending on an input of at least one option pad 240, the semiconductor chip 200a may be configured to swap a correspondence relationship between transmission signals and the plurality of transmission pads 230_TX, or swap a correspondence relationship between reception signals and the plurality of reception pads 230_RX.

Since the power of the transmission signals may be much greater than the power of the reception signals, the design difficulty of semiconductor circuits for generating the transmission signals may be higher than the design difficulty of semiconductor circuits for generating the reception signals, and the arrangement uncertainty of the first and second transmission terminals TX LANE1 and TX LANE2 may be higher than that of the first and second reception terminals RX LANE1 and RX LANE2. Accordingly, when the number of at least one option pad 240 is limited, the swap between the plurality of transmission pads 230_TX may be implemented more preferentially than the swap between the plurality of reception pads 230_RX, but the present disclosure is not limited thereto.

Referring to FIG. 2A, a set of first transmission external terminals 130_TX1 of a plurality of transmission external terminals 130_TX1 and 130_TX2 may be electrically connected to a plurality of first transmission pads (the upper side of 230_TX) of the plurality of transmission pads 230_TX through a first transmission lane of the plurality of lanes 110, and the first transmission lane may include a plurality of first transmission lines. A second set of transmission external terminals 130_TX2 of the plurality of transmission external terminals 130_TX1 and 130_TX2 may be electrically connected to a plurality of second transmission pads (the lower side of 230_TX) of the plurality of transmission pads 230_TX through a second transmission lane of the plurality of lanes 110, and the second transmission lane may include a plurality of second transmission lines. The plurality of transmission pads 230_TX may include a plurality of first transmission lane pads (the upper side of 230_TX) and a plurality of second transmission lane pads (the lower side of 230_TX), and may include a plurality of first transmission line pads (the left side of 230_TX) and a plurality of second transmission line pads (the right side of 230_TX).

Referring to FIG. 2A, a first set of reception external terminals 130_RX1 of a plurality of reception external terminals 130_RX1 and 130_RX2 may be electrically connected to a plurality of first reception pads (the upper side of 230_RX) of a plurality of reception pads 230_RX through a first reception lane of the plurality of lanes 110, and the first reception lane may include a plurality of first reception lines. A second set of reception external terminals 130_RX2 of the plurality of reception external terminals 130_RX1 and 130_RX2 may be electrically connected to a plurality of second reception pads (the lower side of 230_RX) of the plurality of reception pads 230_RX through a second reception lane of the plurality of lanes 110, and the second reception lane may include a plurality of second reception lines. The plurality of reception pads 230_RX may include a plurality of first reception lane pads (the upper side of 230_RX) and a plurality of second reception lane pads (the lower side of 230_RX), and may include a plurality of first reception line pads (the left side of 230_RX) and a plurality of second reception line pads (the right side of 230_RX).

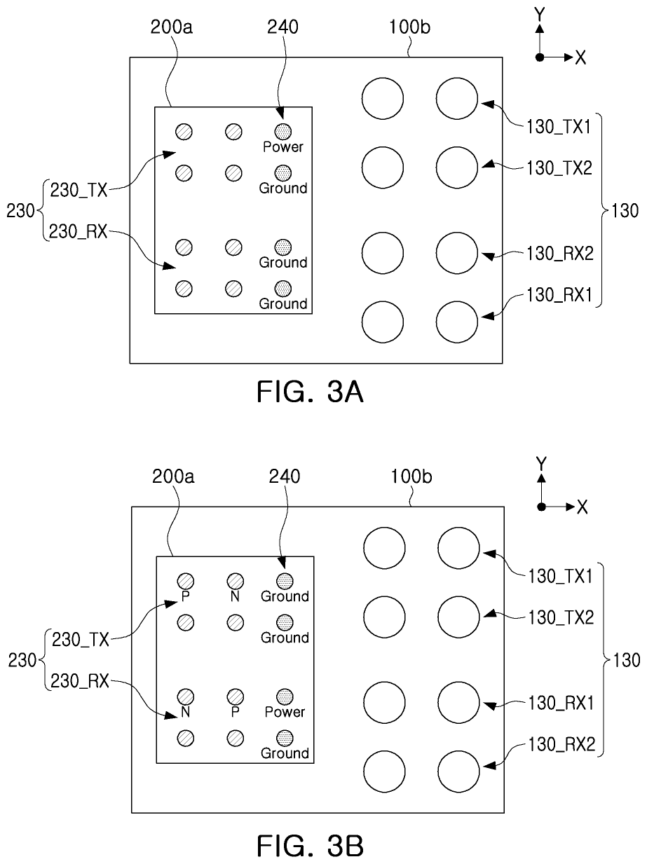

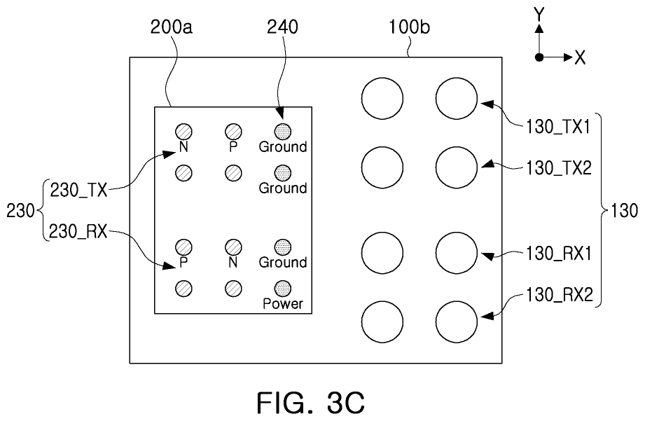

Referring to FIGS. 2A to 3C, at least one option pad 240 may be a plurality of option pads 240, and may be first, second, third, and fourth option pads 240. The first, second, third, and fourth option pads 240 may be connected between the substrates 100a and 100b and the semiconductor chips 200a and 200b. For example, the first, second, third, and fourth option pads 240 may be pads on the semiconductor chips 200a and 200b, connected to wiring in the substrate 100a. FIG. 2C and FIG. 2D illustrate an input of the first option pad (a second order from the top of 240), FIG. 3A illustrates an input of the second option pad (a first order from the top of 240), FIG. 3B illustrates an input of the fourth option pad (a second order from the bottom of 240), and FIG. 3C illustrates an input of the third option pad (a first order from the bottom of 240). Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Ordinal numbers such as “first,” “second,” “third,” etc. may also depict an ordinal relationship between components where the context clearly so indicates.

Referring to FIGS. 2C and 2D, the semiconductor chips 200a and 200b may be configured to swap between the plurality of transmission lane pads (the upper side and the lower side of 230_TX), selectively depending on the input of the first option pad 240 (the second order from the top of 240).

Referring to FIG. 3A, the semiconductor chip 200a may be configured to swap between a plurality of reception lane pads (the upper side and the lower side of 230_RX), selectively depending on the input of the second option pad (the first order from the top of 240).

Referring to FIG. 3B, the semiconductor chip 200a may be configured to swap between a plurality of reception line pads (the left side and the right side of 230_RX), selectively depending on the input of the fourth option pad (the second order from the bottom of 240. For example, the plurality of reception line pads 230_RX may include positive pads P and negative pads N. Locations of the positive pads P and the negative pads N may be shifted by swapping between the plurality of reception line pads.

Referring to FIG. 3C, the semiconductor chip 200a may be configured to swap between a plurality of transmission line pads (the left side and the right side of 230_TX), selectively according to the input of the third option pad (the first order from the bottom of 240). For example, the plurality of transmission line pads 230_TX may include positive pads P and negative pads N. Locations of the positive pads P and the negative pads N may be shifted by swapping between the plurality of transmission line pads.

As described above, the semiconductor chips 200a and 200b may efficiently provide various swaps (e.g., a lane swap, a line swap, and a transmission and reception swap (TX-RX swap)) by subdividing the plurality of option pads 240. As the variety of the swap provided by the semiconductor chip 200a increase, the design optimality of the semiconductor chips 200a and 200b and the design optimality of the plurality of lanes 110 may be improved more flexibly. The variety of swaps provided by the semiconductor chips 200a and 200b may be changed depending on the design of the plurality of lanes 110 and the semiconductor chips 200a and 200b, and may be changed depending on the number of available option pads 240. What the semiconductor chips 200a and 200b have in common is to determine the electrical connection relationship between the plurality of external terminals 130 and a plurality of pads 230 so that the overall length of the plurality of lanes that convey certain types of signals is the shortest, but the present disclosure is not limited thereto.

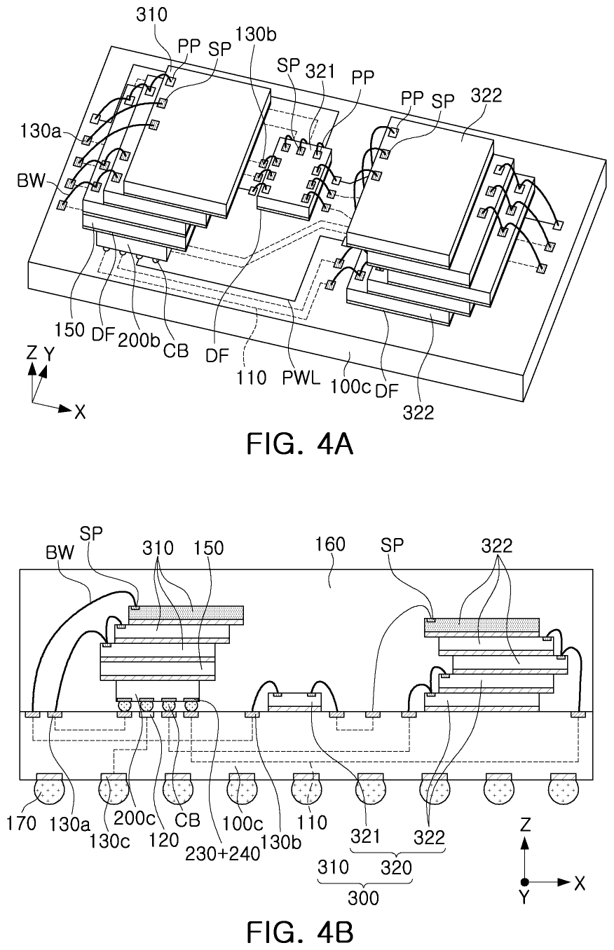

FIGS. 4A and 4B illustrate a structure in which a semiconductor package according to an example embodiment of the present disclosure further includes a plurality of memory chips 310 and 320.

Referring to FIGS. 4A and 4B, a plurality of external terminals 130a, 130b and 130c may be disposed on an upper surface and/or a lower surface of a substrate 100c, and may be electrically connected to at least one of the plurality of memory chips 310 and 320. FIGS. 4A and 4B illustrate a structure in which the plurality of external terminals 130a and 130b are electrically connected to a plurality of pads SP disposed on an upper surface of the plurality of memory chips 310 and 320 through a plurality of bonding wires BW, but the present disclosure not limited thereto. For example, the plurality of external terminals 130a and 130b and the plurality of memory chips 310 and 320 may be electrically connected to each other through at least one of a bump, a solder ball, and a post. For example, the plurality of external terminals 130c may be electrically connected to an additional semiconductor chip or an additional substrate through solder balls 170.

The semiconductor chip 200b may be mounted on an upper surface of the substrate 100c through bumps CB. For example, the bumps CB may be connected and fixed to the semiconductor chip 200b and the substrate 100c through a thermal compression bonding (TCB) process or a reflow process. In this case, a plurality of pads 230 disposed on a lower surface of the semiconductor chip 200b may be electrically connected to a plurality of lanes 110, and a plurality of option pads 240 may be electrically connected to a power line PWL or a ground. After the semiconductor chip 200b is mounted, the input of the plurality of option pads 240 may be fixed. That is, a correspondence relationship between the transmission signals and/or the reception signals of the semiconductor chip 200b and the plurality of pads 230 may be variable before the semiconductor chip 200b is mounted, but the correspondence relationship may be fixed after the semiconductor chip 200b is mounted.

For example, the plurality of memory chips 310 and 320 may include at least one of first memory chips 310, a buffer memory chip 321, and second memory chips 322, and may be memory devices in the form of a high bandwidth memory (HBM) having an increased bandwidth by including a plurality of channels having independent interfaces. The first memory chips 310 may be electrically connected to the semiconductor chip 200b without the buffer memory chip 321, and the second memory chips 322 may be electrically connected to the semiconductor chip 200b through the buffer memory chip 321. The buffer memory chip 321 may buffer command information and address information transmitted or received for the second memory chips 322, and may store a queue. The first and second memory chips 310 and 322 may perform a write operation or a read operation according to the command information and the address information.

For example, each of the plurality of memory chips 310 and 320 may be implemented with a volatile memory (e.g., a static random access memory (SRAM), a dynamic RAM (DRAM), and a synchronous RAM (SDRAM)), or a nonvolatile memory (e.g., a flash memory, a phase-change RAM (PRAM), a magneto-resistive RAM (MRAM), a resistive RAM (ReRAM), and a ferro-electric RAM (FRAM)).

For example, each of the plurality of memory chips 310 and 320 and the semiconductor chip 200b may include a body portion including semiconductor materials such as silicon (Si), germanium (Ge), and gallium (GaAs), and a device layer disposed below the body portion and including an integrated circuit (IC). For example, a plurality of pads 230 and a plurality of option pads 240 disposed on a lower surface of the semiconductor chip 200b may be disposed below the device layer, may be electrically connected to the device layer through a back end of line (BEOL), and may include conductive materials such as tungsten (W), aluminum (Al), copper (Cu).

A plurality of memory chips 310 and 320 may be attached to each other through adhesive layers DF or may be attached to the substrate 100c. A spacer member 150 may be disposed between some of the plurality of memory chips 310 and 320 and the semiconductor chip 200b, and may have a structure in which semiconductor circuits are not present in the semiconductor chip. Depending on the design, some of the plurality of memory chips 310 and 320 and the semiconductor chip 200b may be electrically connected to each other vertically through vias formed vertically inside each of some of the plurality of memory chips 310 and 320 and the semiconductor chip 200b.

An encapsulant 160 such as an epoxy molding composite (EMC) may be filled in a space in which the plurality of memory chips 310 and 320 and the semiconductor chip 200b do not occupy in a space on an upper surface of the substrate 100c, thereby encapsulating the plurality of memory chips 310 and 320 and the semiconductor chip 200b. The power line PWL may be electrically connected to power pads PP disposed on upper surfaces of the plurality of memory chips 310 and 320 and may provide power. For example, the power may be received from the outside through some of the plurality of external terminals 130c, and may also be provided to the semiconductor chip 200b.

The semiconductor chip 200b may be a host for the plurality of memory chips 310 and 320, and may transmit transmission signals to the plurality of memory chips 310 and 320 or receive reception signals from the plurality of memory chips 310 and 320 through a host interface. The host interface may be universal flash storage (UFS), but the present disclosure is not limited thereto. For example, the host interface may be at least one of Peripheral Component Interconnect Express (PCIe), Non-Volatile Memory Express (NVMe), Serial Attached SCSI (SAS), Small Computer System Interface (SCSI), SCSIe, Serial Advanced Technology Attachment (SATA), SATAe, Computer Express Link (CXL), and Gen-Z.

Depending on the design, the plurality of memory chips 310 and 320 may be replaced by a plurality of non-memory chips, and the semiconductor chip 200b may transmit transmission signals to a plurality of non-memory chips, or may receive reception signals from the plurality of non-memory chips through a chiplet interface such as Universal Chip Interconnect Express (UCIe).

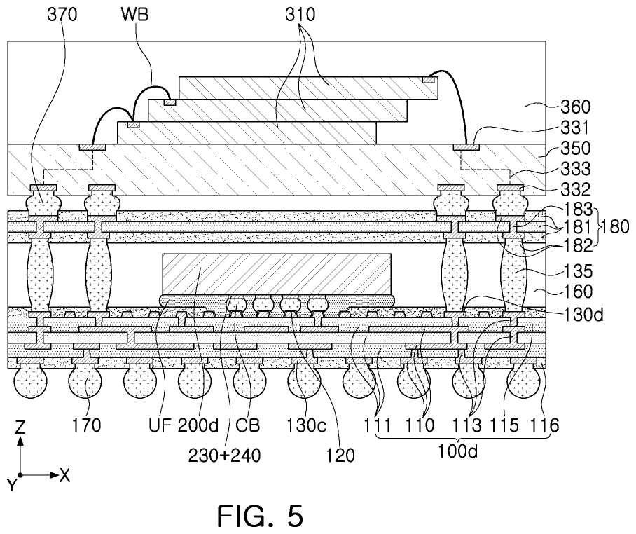

FIG. 5 illustrates a package on package (PoP) structure in which a semiconductor package according to an example embodiment of the present disclosure may have.

Referring to FIG. 5, a substrate 100d may have a structure in which a plurality of insulating layers 111 and a plurality of wiring layers are alternately stacked, and the plurality of wiring layers may be vertically connected through conductive vias 113. A plurality of lanes 110 may be implemented by the plurality of wiring layers and the conductive vias 113. Cover layers 115 and 116 such as solder resist may provide an upper surface and a lower surface of the substrate 100d and expose substrate pads 120 upwardly. The substrate pads 120 may be electrically connected to the plurality of lanes 110. For example, the plurality of insulating layers 111 may include insulating materials such as prepreg, Ajinomoto Build-up Film (ABF), Photoimageable Dielectric (PID), FR-4 (Flame Retardant), Bismaleimide Triazine (BT), and an epoxy resin, and the plurality of lanes 110 may include copper (Cu), aluminum (Al), silver (Ag), tin (Sn), gold (Au), nickel (Ni), lead (Pb), titanium (Ti), or alloys thereof.

The semiconductor chip 200d may be mounted on the substrate pads 120 of the substrate 100d through bumps CB. An underfill layer UF may come into contact with the bumps CB, may surround the bumps CB, and may include a nonconductive polymer or a nonconductive paste (NCP).

Posts 135 may be formed on a plurality of external terminals 130d on an upper surface of the substrate 100d and may be electrically connected to the plurality of external terminals 130d. An encapsulant 160 may encapsulate the posts 135 and the semiconductor chip 200d.

A wiring structure 180 may be disposed on an upper surface of the encapsulant 160, and may have a structure in which additional insulating layers 181 and additional wiring layers 182 are alternately stacked. The additional wiring layers 182 may be vertically connected through additional conductive vias 183 and may be electrically connected to the posts 135.

An additional substrate 350 may be disposed on an upper surface of a wiring structure 180 and may be electrically connected to the wiring structure 180 through solder balls 370. The additional substrate 350 may include upper pads 331 disposed on an upper surface of the additional substrate 350, lower pads 332 disposed on a lower surface of the additional substrate 350, and additional wiring layers 333 electrically connected between the upper pads 331 and the lower pads 332, and may be manufactured in a manner similar to the substrate 100d.

The plurality of memory chips 310 may be disposed on the additional substrate 350 and may be electrically connected to the additional substrate 350 through bonding wires WB. An encapsulant 360 such as an epoxy molding composite (EMC) may encapsulate the plurality of memory chips 310 and the bonding wires WB on an upper surface of the additional substrate 350.

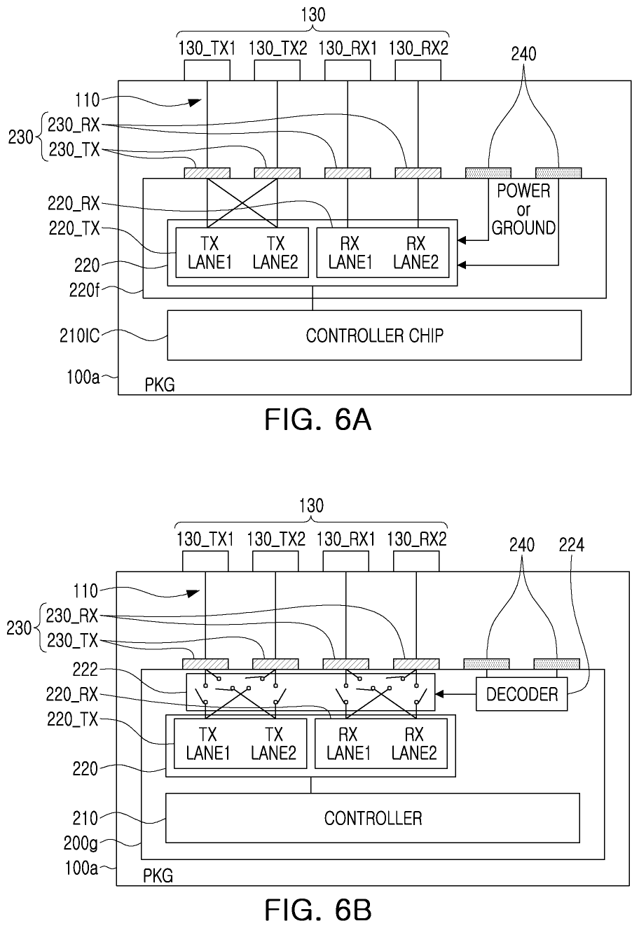

Referring to FIG. 6A, a semiconductor package according to an example embodiment of the present disclosure may further include a control chip 210IC, and a semiconductor chip 100f may not include the control circuit 210 of FIG. 1A. That is, according to the design, the semiconductor chip 100a of FIG. 1A may be divided into a plurality of semiconductor chips.

Referring to FIG. 6B, a semiconductor chip 200g of the semiconductor package according to an example embodiment of the present disclosure may further include a switch circuit 222 and/or a decoder circuit 224.

Selectively depending on the input of at least one option pad 240, the switch circuit 222 may be configured to swap an electrical connection relationship between plurality of transmission terminals TX LANE1 and TX LANE2 of an interface circuit 220 and a plurality of transmission pads 230_TX, or swap an electrical connection relationship between a plurality of reception terminals RX LANE1 and RX LANE2 of the interface circuit 220 and a plurality of reception pads 230_RX.

For example, the switch circuit 222 may include a plurality of switches, and each of the plurality of switches may be configured to switch whether or not to have an electrical connection between a drain terminal and a source terminal according to a switching signal input to a gate terminal of a semiconductor transistor. The decoder circuit 224 may transfer the switching signal to the switch circuit 222 and convert the input of at least one option pad 240 into the switching signal. For example, the default and swapping examples described in any of FIGS. 1A-3C may be implemented using a switch circuit and decoder such as shown in FIG. 6B.

A semiconductor package according to an example embodiment of the present disclosure can flexibly improve the design optimality of lanes and/or a semiconductor chip of a semiconductor package.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor package comprising:
a plurality of transmission external terminals;
a plurality of reception external terminals;
a semiconductor chip including a plurality of transmission pads, a plurality of reception pads, and at least one option pad;
a plurality of transmission lanes electrically connected between the plurality of transmission external terminals and the plurality of transmission pads; and
a plurality of reception lanes electrically connected between the plurality of reception external terminals and the plurality of reception pads,
wherein the semiconductor chip is configured to swap signals or connections for the plurality of transmission pads, or swap signals or connections for the plurality of reception pads, selectively depending on an input of the at least one option pad.

2. The semiconductor package of claim 1, wherein the semiconductor chip comprises an interface circuit configured to generate transmission signals or convert reception signals according to a specific interface manner, and
the semiconductor chip is configured to swap a correspondence relationship between the transmission signals and the plurality of transmission pads, or swap a correspondence relationship between the reception signals and the plurality of reception pads, selectively depending on the input of the at least one option pad.

3. The semiconductor package of claim 1, wherein the semiconductor chip comprises:
an interface circuit configured to generate transmission signals or convert reception signals according to a specific interface manner; and
a switch circuit configured to swap an electrical connection relationship between a plurality of transmission terminals of the interface circuit and the plurality of transmission pads, or swap an electrical connection relationship between a plurality of reception terminals of the interface circuit and the plurality of reception pads, selectively depending on the input of the at least one option pad.

4. The semiconductor package of claim 1, wherein, selectively according to the input of at least one option pad,
an electrical connection relationship between the plurality of transmission external terminals and the plurality of transmission pads is determined so that an overall length of the plurality of transmission lanes for a particular type of signal is shorter than an overall length of transmission lanes for another type of signal, or
an electrical connection relationship between the plurality of reception external terminals and the plurality of reception pads is determined so that an overall length of the plurality of reception lanes for a particular type of signal is shorter than an overall length of transmission lanes for another type of signal.

5. The semiconductor package of claim 1, wherein the plurality of transmission pads are a plurality of transmission lane pads formed in a plurality of lanes,
each of the lanes includes a plurality of transmission line pads, and
the semiconductor chip is configured to swap signals or connections for the plurality of transmission lane pads, or swap signals or connections for the plurality of transmission line pads, selectively depending on the input of the at least one option pad.

6. The semiconductor package of claim 1, wherein the at least one option pad is a plurality of option pads,
the plurality of transmission pads are a plurality of transmission lane pads formed in a plurality of lanes,
each of the plurality of lanes includes a plurality of transmission line pads,
the semiconductor chip is configured to swap signals or connections for the plurality of transmission lane pads, selectively depending on an input of a first set of the plurality of option pads, and
the semiconductor chip is configured to swap signals or connections for the plurality of transmission line pads, selectively depending on an input of a second set of the plurality of option pads.

7. The semiconductor package of claim 1, wherein the at least one option pad is a plurality of option pads,
The plurality of transmission pads are a plurality of transmission lane pads formed in a plurality of transmission lanes,
each transmission lane includes a plurality of transmission line pads,
the plurality of reception pads are a plurality of reception lane pads formed in a plurality of reception lanes,
each reception lane includes a plurality of reception line pads,
the semiconductor chip is configured to swap signals or connections for the plurality of transmission lane pads, or swap signals or connections for the plurality of reception lane pads, selectively depending on an input of a first set of the plurality of option pads, and
the semiconductor chip is configured to swap signals or connections for the plurality of transmission line pads, or swap signals or connections for the plurality of reception line pads, selectively depending on an input of a second set of the plurality of option pads.

8. The semiconductor package of claim 1, wherein the at least one option pad is a plurality of option pads,
the semiconductor chip is configured to swap signals or connections for the plurality of transmission pads, selectively depending on an input of a first set of the plurality of option pads, and
the semiconductor chip is configured to swap signals or connections for the plurality of reception pads, selectively depending on an input of a second set of the plurality of option pads.

9. The semiconductor package of claim 1, wherein the at least one option pad includes first, second, third, and fourth option pads,
the plurality of transmission pads are a plurality of transmission lane pads formed in a plurality of transmission lanes,
each transmission lane includes a plurality of transmission line pads,
the plurality of reception pads are a plurality of reception lane pads formed in a plurality of reception lanes,
each reception lane includes a plurality of reception line pads,
the semiconductor chip is configured to swap signals or connections for the plurality of transmission lane pads, selectively depending on an input of the first option pad,
the semiconductor chip is configured to swap signals or connections for the plurality of reception lane pads, selectively depending on an input of the second option pad,
the semiconductor chip is configured to swap signals or connections for the plurality of transmission line pads, selectively depending on an input of the third option pad,
the semiconductor chip is configured to swap signals or connections for the plurality of reception line pads, selectively depending on an input of the fourth option pad.

10. The semiconductor package of claim 1, further comprising:
a substrate on which at least one wiring layer and at least one insulating layer are alternately stacked,
wherein the plurality of transmission lanes and the plurality of reception lanes are included in the at least one wiring layer,
the plurality of transmission external terminals and the plurality of reception external terminals are disposed on the substrate, and
the input of the at least one option pad is fixed at least after the semiconductor chip is electrically connected to the substrate.

11. The semiconductor package of claim 1, wherein the at least one option pad is electrically connected to power or a ground, and
the semiconductor chip is configured to swap signals or connections for the plurality of transmission pads, or swap signals or connections for the plurality of reception pads, depending on whether the input of the at least one option pad is the power or the ground.

12. The semiconductor package of claim 1, wherein a data transmission rate of each of the transmission signals passing through the plurality of transmission lanes and the reception signals passing through the plurality of reception lanes exceeds 3 Gbps.

13. The semiconductor package of claim 1, further comprising:
at least one memory chip electrically connected to the transmission external terminals and the reception external terminals,
wherein the semiconductor chip transmits transmission signals according to an M-PHY of the Mobile Industry Processor Interface (MIPI) through the plurality of transmission pads and receives reception signals according to the M-PHY of the MIPI through the plurality of reception pads.

14. A semiconductor package comprising:
a plurality of external terminals;
a semiconductor chip including a plurality of lane pads formed in a plurality of lanes, and a plurality of option pads; and
a plurality of lanes electrically connected between the plurality of external terminals and the plurality of lane pads,
wherein each set of the plurality of lane pads includes a plurality of line pads,
the semiconductor chip is configured to swap signals or connections for the plurality of lane pads, selectively depending on an input of a first set of the plurality of option pads, and
the semiconductor chip is configured to swap signals or connections for the plurality of line pads, selectively depending on an input of a second set of the plurality of option pads.

15. The semiconductor package of claim 14, wherein the semiconductor chip includes an interface circuit configured to generate or convert signals according to a specific interface manner,
the semiconductor chip is configured to swap a correspondence relationship between the signals and the plurality of lane pads, or swap an electrical connection relationship between a plurality of terminals of the interface circuit and the plurality of lane pads, selectively depending on the input of the first set of the plurality of option pads, and
the semiconductor chip is configured to swap a correspondence relationship between the signals and the plurality of line pads, or swap an electrical connection relationship between the plurality of terminals of the interface circuit and the plurality of line pads, selectively depending on the input of the second set of the plurality of option pads.

16. The semiconductor package of claim 14, wherein, selectively depending on the input of the first set of the plurality of option pads, an electrical connection relationship between the plurality of external terminals and the plurality of lane pads is determined so that an overall length of the plurality of lanes for a particular type of signal is shorter than an overall length of the plurality of lanes for another type of signal, and
selectively depending on an input of the second set of the plurality of option pads, an electrical connection relationship between the plurality of external terminals and the plurality of line pads is determined so that an overall length of the plurality of lanes for a particular type of signal is shorter than an overall length of the plurality of lanes for another type of signal.

17. The semiconductor package of claim 14, further comprising:
a substrate on which at least one wiring layer and at least one insulating layer are alternately stacked,
wherein the plurality of lanes are included in the at least one wiring layer,
the plurality of external terminals are disposed on the substrate, and
the input of the plurality of option pads is fixed at least after the semiconductor chip is electrically connected to the substrate.

18. The semiconductor package of claim 14, further comprising:
at least one memory chip electrically connected to the plurality of external terminals,
wherein a data transmission rate of the signals passing through the plurality of lanes exceeds 3 Gbps.

19. A semiconductor package comprising:
a plurality of transmission external terminals;
a plurality of reception external terminals;
a semiconductor chip including a plurality of transmission pads and a plurality of reception pads;
a plurality of transmission lanes electrically connected between the plurality of transmission external terminals and the plurality of transmission pads; and
a plurality of reception lanes respectively electrically connected between the plurality of reception external terminals and the plurality of reception pads,
wherein the semiconductor chip includes an interface circuit configured to generate transmission signals or convert reception signals according to a specific interface manner, and
the semiconductor chip is configured so that at least one of an electrical connection relationship between a plurality of transmission terminals of the interface circuit and the plurality of transmission pads and an electrical connection relationship between a plurality of reception terminals of the interface circuit and the plurality of reception pads is switched from a variable state to a fixed state.

20. The semiconductor package of claim 19, further comprising:
a substrate on which at least one wiring layer and at least one insulating layer are alternately stacked,
wherein the plurality of transmission lanes and the plurality of reception lanes are included in the at least one wiring layer,
the plurality of transmission external terminals and the plurality of reception external terminals are disposed on the substrate, and
at least one of the electrical connection relationship between the plurality of transmission terminals of the interface circuit and the plurality of transmission pads and the electrical connection relationship between the plurality of reception terminals of the interface circuit and the plurality of reception pads is fixed at least after the semiconductor chip is electrically connected to the substrate.
